(19) United States
(12) Patent Application Publication
(10) Pub. No.: US 2008/0285213 A1
(43) Pub. Date: Nov. 20, 2008

(54) Keyboard With Media Device Docking Station

(76) Inventors: Min-Liang Tan, Singapore (SG); Chern Ann Ng, Singapore (SG)

Correspondence Address: ANDREW G. DINOVO;DiNOVO PRICE ELLWANGER & HARDY LLP, 7000 N. MOPAC EXPRESSWAY, SUITE 350, AUSTIN, TX, 78731, US

(21) Appl. No.: 12/096,149

(22) PCT Filed: Jan. 27, 2006
(86) PCT No.: PCT/US06/03145

§ 371 Date: Aug. 6, 2008

(30) Foreign Application Priority Data
Dec. 7, 2005 (US) PCT/US05/44153

(51) Int. Cl. G06F 1/16; H05K 13/00

(52) U.S. Cl. 361/680; 29/729

(57) ABSTRACT

Method and system are disclosed for a keyboard (200) having a built-in docking station (204) for a handheld media device. The built-in docking station allows the handheld media device to be accessed from the computer and also recharged in some cases without requiring any additional setup or adding clutter to the computer work area, since the keyboard is already set up in the work area. In some embodiments, keyboard key codes may be intercepted and routed directly to the docking station, thus allowing the handheld media device to be accessed from the keyboard independently of the computer. Alternatively (or in addition), the keyboard may have a built-in media reader (406) for accessing a removable memory of the handheld media device. In some embodiments, a video display (606) and/or speakers (506) for the handheld media device may also be built-in the keyboard.

### FIELD OF THE INVENTION

The present invention relates generally to keyboards and, more particularly, to a keyboard having a built-in docking station for a portable handheld media device.

### BACKGROUND OF THE INVENTION

The emergence of low-cost, high-density solid state memory (e.g., flash memory) combined with improvements in battery technology have given rise to a number of new consumer electronic applications. Perhaps the most popular among these applications is the ubiquitous portable handheld media device (e.g., digital cameras, MP3 players, iPod™). These handheld media devices allow consumers to quickly and easily store, organize, transmit, and otherwise manipulate a large number of data, audio, and video files. The advantage of such handheld media devices is their small size, which makes it convenient for consumers to carry them around. But because of their small size, the displays (if any) and control buttons on these handheld media devices are typically difficult to see and operate and have very limited functionality. Thus, these devices normally need to be connected to a desktop or laptop computer in order for the consumer to organize, transmit, or manipulate the data, audio, or video files.

The connection to the desktop or laptop computer is typically achieved via a removable interface cable, such as a USB (Universal Serial Bus) or FireWire (IEEE 1394) cable, that connects the handheld media device to the computer's interface port. The consumer may then access the data, audio, or video files stored on the handheld media device from his/her computer. The interface cable, however, is somewhat unsightly and can clutter and entangle the work area around the consumer's computer. In addition, a separate battery charger and power cable are usually required to recharge the battery of the handheld media device. The battery charger and power cable can further add to the unsightliness and clutter of the work area around the consumer's computer.

More recently, docking stations have been developed for handheld media devices that combine the functions of the interface cable and the battery charger in a single, more aesthetically pleasing package. FIG. 1A is a conceptual illustration of the docking station relative to the work area around the consumer's computer. As can be seen, a typical computer 100 has a monitor display 102, a keyboard 104, and a pointing device (mouse) 106. These components together constitute the minimum required components for operating the computer 100. Other devices that may be added include a printer, scanner, modem, and so forth. These auxiliary devices, however, can quickly clutter up the work area around the computer 100, depending on the number and type of devices. To avoid even further cluttering of an already cluttered work area, a media device docking station 108 may be connected to the computer 100. The media device docking station 108 takes the place of the interface cable, battery charger, and power cable.

FIG. 1B is a close-up view of the media device docking station 108. As can be seen from this view, the docking station 108 is composed primarily of a cradle 110 having an interface connector 112 protruding therefrom. A docking station chord 114 for carrying power and communication signals to and from the computer 100 connects the interface connector 112 to the media device port of the computer 100. A corresponding interface connector 116 is provided on the handheld media device 118 (e.g., at the bottom thereof) for mating with the interface connector 112 of the docking station 108 when the handheld media device 118 is placed in the docking station 108. The interface connectors 112 and 116 may be any suitable industry-standard connectors (e.g., USB, FireWire, etc.) for allowing the computer 100 to communicate with the handheld media device 118.

Although the media device docking station 108 is an improvement over the separate interface cable, battery charger, and power cable, it still takes up space and can clutter the work area around the consumer's computer. Accordingly, what is needed is a way to connect the handheld media device to the computer and also to recharge the device in some cases without creating additional clutter in the work area around the computer.

### SUMMARY OF THE INVENTION

The present invention relates to a method and system for connecting a handheld media device to a computer without creating additional clutter in the work area around the computer. The method/system of the invention involves providing a built-in docking station for the handheld media device on a keyboard of the computer. Such a built-in docking station allows the handheld media device to be accessed from the computer and also recharged in some cases without requiring additional setup or adding clutter to the computer work area, since the keyboard is already part of the work area. In some embodiments, keyboard key codes may be intercepted and routed directly to the docking station, thus allowing the handheld media device to be accessed from the keyboard independently of the computer. Alternatively (or in addition), the keyboard may have a built-in media reader for accessing a removable memory of the handheld media device. In some embodiments, a video display and/or speakers for the handheld media device may also be built-in to the keyboard.

In general, in one aspect, the invention is directed to a method of assembling a computer keyboard. The method comprises the steps of providing a keyboard body having a plurality of keyboard keys thereon and building a handheld media device docking station into the keyboard body, the handheld media device docking station configured to receive a handheld media device. The method further comprises the step of connecting the handheld media device docking station to a media device cable, the media device cable adapted for carrying data between the handheld media device and a computer.

In general, in another aspect, the invention is directed to a computer keyboard. The computer keyboard comprises a keyboard body having a plurality of keyboard keys thereon and a handheld media device docking station built-in to the keyboard body. The docking station is configured to receive a handheld media device. The computer keyboard further comprises a media device cable connected to the handheld media device docking station and adapted for carrying data between the handheld media device and a computer.

In general, in still another aspect, the invention is directed to a computer keyboard. The computer keyboard comprises a keyboard body having a plurality of keyboard keys thereon and a handheld media device docking station built-in to the keyboard body. The docking station is configured to receive a handheld media device. The computer keyboard further comprises a media device cable connected to the handheld media device docking station and adapted for carrying data between the handheld media device and a computer and a key controller within the keyboard body adapted to generate key codes for the keyboard. A tap is connected to the key controller and the handheld media device docking station, the tap being operable to route a copy of the key codes generated by the key controller to the handheld media device docking station. The computer keyboard finally comprises means for providing power to the handheld media device docking station and the keyboard independently of the computer.

Other advantages and features of the invention will become apparent from the following descriptions, the drawings, and the claims.

### BRIEF DESCRIPTION OF THE DRAWINGS

The foregoing and other advantages of the invention will become apparent from the following detailed description and upon reference to the drawings, wherein:

FIGS. 1A-1B are a perspective view and a top view, respectively, of a prior art media device docking station;

FIG. 2 is a keyboard having a built-in media device docking station according to embodiments of the invention;

FIG. 3 is a keyboard having a media device docking station attached thereto according to embodiments of the invention;

FIG. 4 is a keyboard having a built-in media reader according to embodiments of the invention;

FIG. 5 is a keyboard having a built-in docking station and speakers for the docking station according to embodiments of the invention;

FIG. 6 is a keyboard having a built-in docking station and a video display for the docking station according to embodiments of the invention;

FIG. 7 is a keyboard having a built-in docking station, a video display, and speakers for the docking station according to embodiments of the invention;

FIG. 8 is a block diagram of a keyboard with a built-in media device docking station according to embodiments of the invention;

FIG. 9 is a block diagram of another keyboard with a built-in docking station according to embodiments of the invention; and

FIG. 10 is a block diagram of a keyboard with a built-in docking station, video display, and speakers for the docking station according to embodiments of the invention.

### DESCRIPTION OF ILLUSTRATIVE EMBODIMENTS

Following is a detailed description of illustrative embodiments of the invention with reference to the drawings wherein the same reference labels are used for the same or similar elements. It should be noted that the drawings are provided for illustrative purposes only and are not drawn to any particular dimensional scale and do not suggest a preference for any particular configuration.

As alluded to above, embodiments of the invention provide a computer keyboard having a built-in docking station for a handheld media device. The terms “built-in,” “building in,” or “built in,” as used herein, mean that the docking station (and/or other components) may be a separate component that is mounted to or otherwise attached to the keyboard, or that the docking station may be an integral component of the keyboard (i.e., formed as a unitary piece with the keyboard), or a combination of both (i.e., part of the docking station is a separate component mounted on the keyboard and part of it is integral with the keyboard).

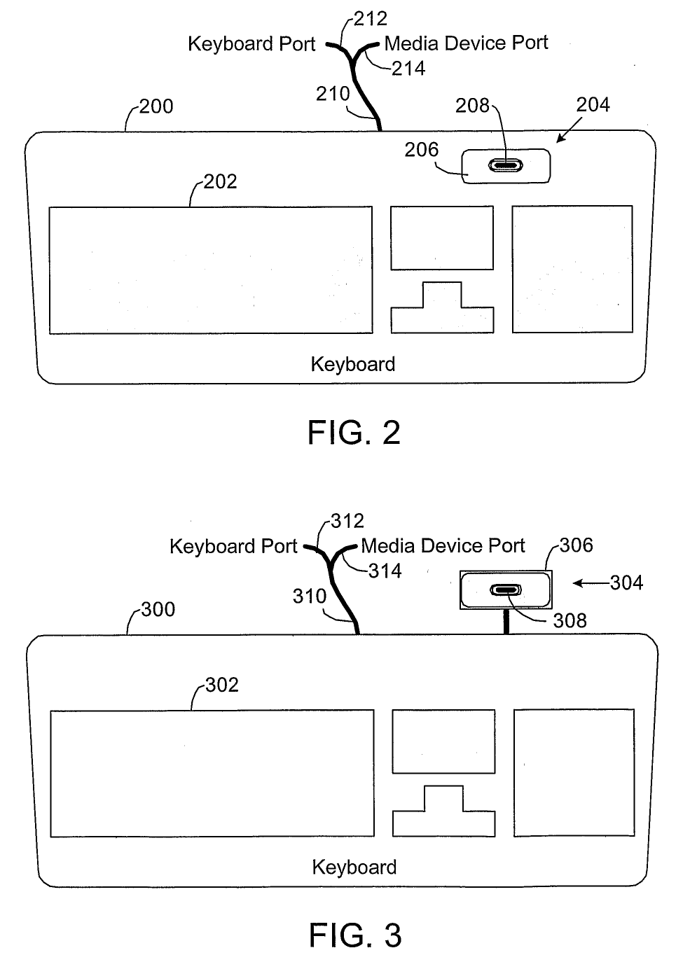

FIG. 2 illustrates a conceptual illustration of a computer keyboard 200 according to one embodiment of the invention. The keyboard 200 is similar in size, shape, and layout to standard computer keyboards, with keys 202 that are arranged in the familiar “QWERTY” pattern. Other keyboard layouts and/or key patterns designed to accommodate, for example, different alphabets or character sets may also be used without departing from the scope of the invention. Unlike standard computer keyboards, however, the keyboard 200 has a docking station 204 for a handheld media device built into the keyboard 200. The built-in docking station 204 allows handheld media devices to be interfaced to a computer without creating additional clutter around the computer, since the keyboard is already present.

In one embodiment, the built-in docking station 204 is composed of a seat 206 in the body of the keyboard 200 and an interface connector 208 protruding therefrom. The seat 206 holds the handheld media device (not expressly shown) on the keyboard 200 and may be flattened and recessed relative to the body of the keyboard 200 to better retain the handheld media device. The handheld media device may be any suitable handheld media device, including digital cameras (image and video), MP3 players, iPod™, and the like. The interface connector 208 obtrudes from the keyboard 200 near the center of the seat 206 and may be any one of several interface connectors suitable for handheld media devices, including a USB connector, a FireWire connector, customized versions of the USB and FireWire connectors, and the like. Such a seat 206 and interface connector 208 together allow the handheld media device to be docked directly to the keyboard 200.

Once docked, a keyboard chord 210 connects the handheld media device to a computer (not expressly shown), such as a laptop or desktop computer. In one embodiment, the keyboard chord 210 is composed of two cables bundled together: a keyboard cable 212 and a media device cable 214. The keyboard cable 212 carries key codes from the keyboard 200 to a keyboard port of the computer, while the media device cable 214 carries media device signals to/from the built-in docking station 204 from/to a media port of the computer. The keyboard cable 212 may be any suitable keyboard cable known to those having ordinary skill in the art, including a PS/2 cable, a USB cable, modified versions of the PS/2 and USB cables, and the like. The media device cable 214 may also be any suitable media device cable known to those having ordinary skill in the art that is compatible with the interface connector 208.

Certain handheld media devices are capable of being recharged through the same media device cable used for computer access. For these handheld media devices, the media device cable 214 may also carry power (via the computer) for recharging the handheld media device. Thus, for these embodiments, the handheld media device may be accessed as well as recharged without creating additional clutter on the work area around the computer. It is also possible to provide a separate power cable (not expressly shown) for the built-in docking station 204, either apart from or bundled with the keyboard chord 210, for recharging the handheld media device. The connector (i.e., the end that is plugged into the handheld media device) for such a power cable may then be mounted in an appropriate location on the built-in docking station 204.

To assemble, the seat 206 may be formed as an integral part of the body of the keyboard 200 or as a separate piece that is attached to or mounted over an opening in the top face of the body of the keyboard 200. In either case, an opening in the seat 206 near the center thereof allows the interface connector 208 to be positioned in the seat 206. The media device cable 214, which may be pre-bundled with the keyboard chord 210, may then be routed through the body of the keyboard 200 and connected to the interface connector 208. Preferably, the dimensions (i.e., length, width, depth) of the seat 206 are sufficient to accommodate multiple brands/types of handheld media devices, but may of course be customized to suit a particular brand/type of handheld media device as needed. Other components of the keyboard 200 (e.g., the keys 202, etc.) may be assembled in conjunction with the docking station 204 in a manner known to those having ordinary skill in the art.

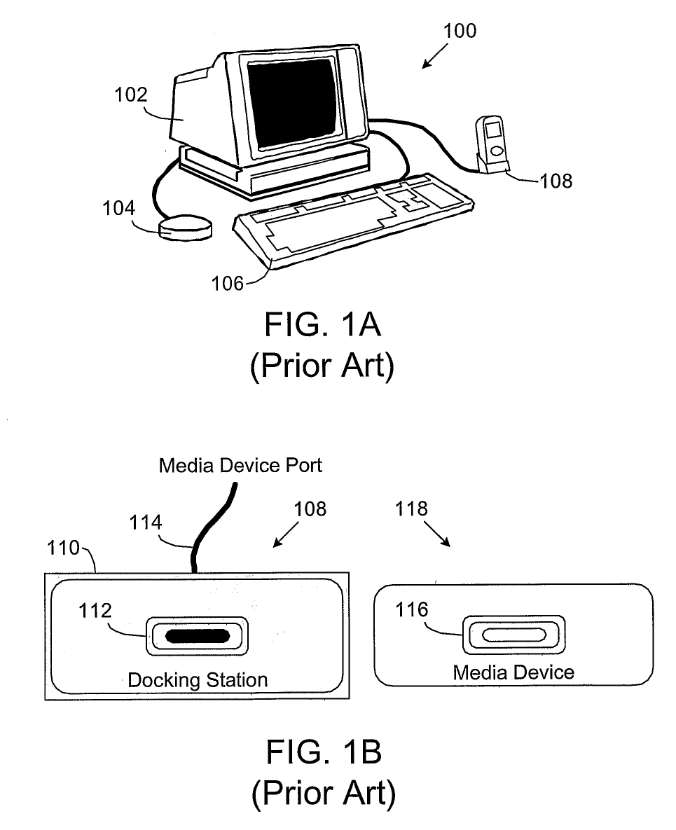

FIG. 3 illustrates another keyboard 300 of the invention where a docking station 304 rests on the top face of the keyboard 300 instead of being recessed into the keyboard 300. The built-in docking station 304 in this example is similar to the docking station 108 of FIG. 1B in that it is composed of a cradle 306 having an interface connector 308 (e.g., USB, FireWire, customized versions thereof, etc.) protruding therefrom. Unlike the docking station 108 of FIG. 1B, however, the built-in docking station 304 is affixed to the keyboard 300 and therefore does not take up any space in the work area around the computer. A keyboard chord 310 having a keyboard cable 312 and a media device cable 314 connects the keyboard 300 and the built-in docking station 304 to the computer in a manner similar to that described for the keyboard chord 210 of FIG. 2. Recharging of the handheld media device may be performed through the media device cable 314 or a separate power cable in the manner described for the keyboard chord 210 of FIG. 2.

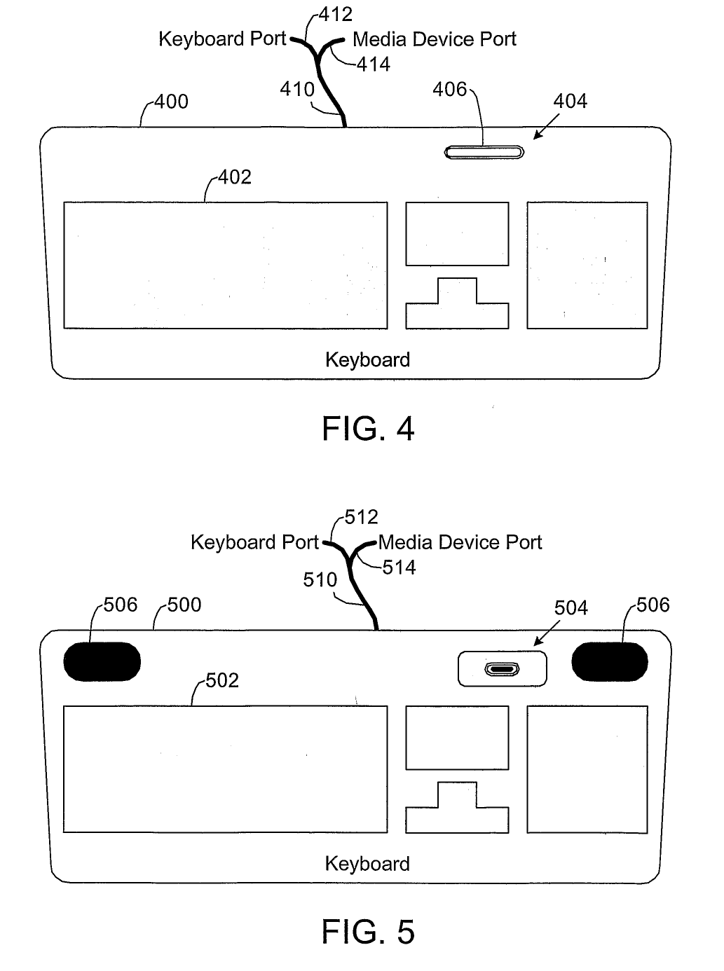

FIG. 4 illustrates yet another keyboard 400 of the invention in which the docking station 404 is composed of a media reader 406 for receiving a removable memory (not expressly shown) of the handheld media device. The built-in media reader 406 resides in an opening in the keyboard 400 in this example, but may also be disposed on the top face of the keyboard 400 so that it is resting on the keyboard 400. Such a built-in media reader 406 allows the removable memory of the handheld media device to be accessed from a computer without creating additional clutter on the work area around the computer. A keyboard chord 410 having a keyboard cable 412 and a media device cable 414 connects the keyboard 400 and the built-in media reader 406 to the computer in a manner similar to that described for the keyboard chord 210 of FIG. 2.

FIG. 5 illustrates still another keyboard 500 of the invention where, in addition to a built-in docking station 504, one or more speakers 506 are built in to the keyboard 500. This keyboard 500 is similar to the keyboard 200 of FIG. 2 insofar as the built-in docking station 504 and the keyboard chord 510 are concerned, but the presence of the built-in speakers 506 allows audio files stored in the handheld media device to be played back while the handheld media device is docked in the built-in docking station 504. Power for the built-in speakers 506 may be provided via the handheld media device itself, through the media device cable 514, by a power cable (either separately or bundled with the keyboard chord 510), or from a portable power supply such as a battery mounted in the keyboard 500. Where the handheld media device itself, a power cable, or a battery is used, it may be possible to access the audio files without turning on the computer first.

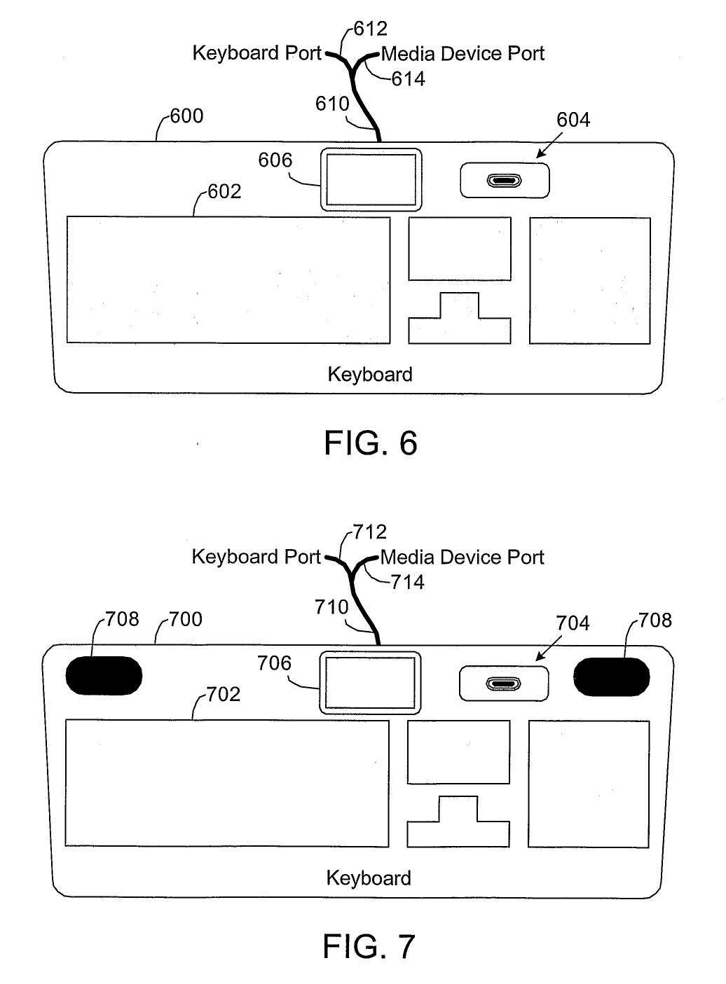

FIG. 6 illustrates yet another keyboard 600 according to embodiments of the invention where a programmable display 606, such as a miniature LCD (liquid crystal display), is built in to the keyboard 600. The built-in programmable display 606 allows video/picture files stored in the handheld media device to be viewed while the handheld media device is docked in the built-in docking station 604. A user may also perform various functions on the handheld media device using the built-in programmable display 606, such as editing a media playlist, manipulating data, audio, and/or video files, and the like. It is also possible to display graphics on the built-in programmable display 606, such as a graphics equalizer, various visualization modes (e.g., bars, lines, waves, etc.), and so forth, during operation of the handheld media device.

Power for the built-in programmable display 606 may be provided via the handheld media device itself, through the media device cable 614, by a power cable (either separately or bundled with the keyboard chord 610), or from a portable power supply such as a battery mounted in the keyboard 600. Thus, where the handheld media device itself, a power cable, or a battery is used, it is not necessary to turn on the computer first before viewing the built-in programmable display 606.

An advantage of the built-in programmable display 606 is that no additional space around the work area of the consumer's computer is consumed, since a keyboard is already a necessary component. In addition, the built-in programmable display 606 provides a much more complete interface for the handheld media device compared to interfaces that are typically available on handheld media devices. Moreover, as mentioned above, it may not even be necessary for the user to turn on his/her computer first to enjoy graphics-based features, such as a graphics equalizer, that may be displayed on the built-in programmable display 606, provided the handheld media device itself, a power cable, or a battery is used to power the display 606. Furthermore, the on-board memory of the built-in programmable display 606 may be upgraded in some embodiments to accommodate new versions of handheld media players and/or to add new features or update existing features. Optionally, the built-in programmable display 606 may also be controlled through the consumer's computer, thereby providing the consumer with additional functionality.

FIG. 7 illustrates a keyboard 700 of the invention where both a display 706 (e.g., an LCD) and speakers 708 are built in to the keyboard 700. In this regard, the keyboard 700 is essentially a combination of the keyboard 500 of FIG. 5 and the keyboard 600 of FIG. 6 and includes the advantages of both keyboards 500 and 600. Such a keyboard 700 allows video/picture and audio files in the handheld media device to be viewed and played back while the handheld media device is docked in the built-in docking station 704. Various functions may also be performed on the handheld media device using the built-in programmable display, such as editing a media playlist, manipulating data, audio, and/or video files, and the like. It is also possible to display graphics on the built-in programmable display, such as a graphics equalizer, various visualization modes (e.g., bars, lines, waves, etc.), and so forth, during operation of the handheld media device. Power may be provided via the handheld media device itself, through the media device cable 714, by a power cable (either separately or bundled with the keyboard chord 710), or from a portable power supply such as a battery mounted in the keyboard 700.

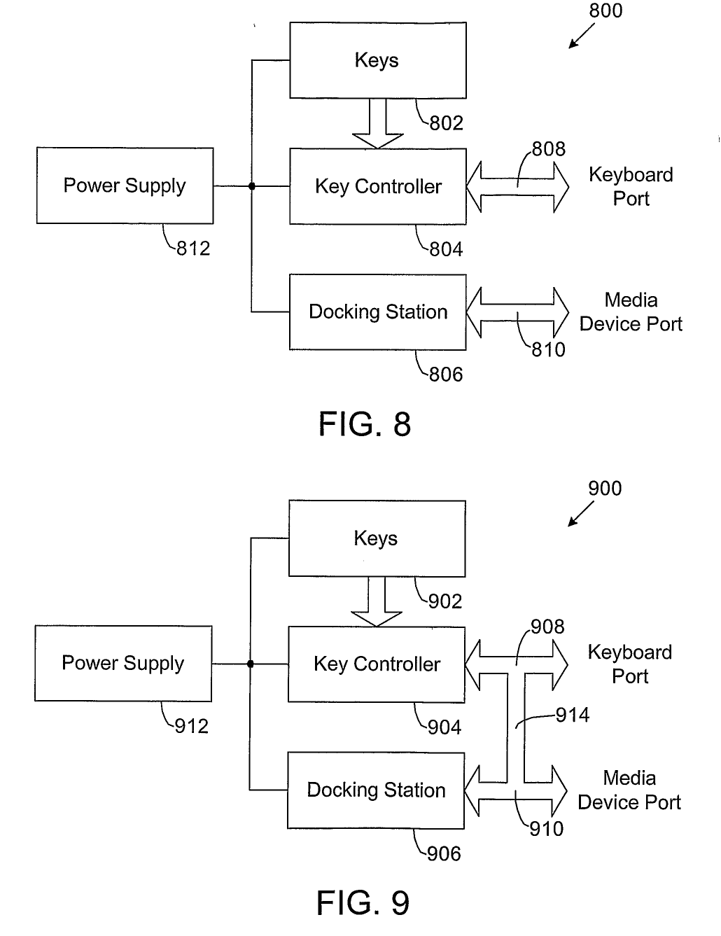

A functional block diagram of an exemplary keyboard 800 according to one embodiment of the invention is shown in FIG. 8. The keyboard 800 includes a plurality of keys 802 (e.g., foam rubber-based keys, capacitive keys, etc.) and a key controller 804 (e.g., a microprocessor, microcontroller, digital signal processor, etc.) electrically connected to the keys 802. The keyboard 800 further includes a built-in docking station 806 for receiving and connecting a handheld media device to the computer without creating additional clutter around the computer work area. In this regard, the keyboard 800 is similar to the keyboards 200, 300, and 400 of FIGS. 2, 3, and 4, respectively. Indeed, the functional block diagram of FIG. 8 may be representative of the keyboards 200, 300, and 400 of FIGS. 2, 3, and 4, respectively, with the docking station 806 of FIG. 8 standing for the docking stations 204, 304, and 404, of FIGS. 2, 3, and 4, respectively.

In operation, each key 802 provides a uniquely identifiable input signal to a key controller 804 when pressed. Upon receiving the input signal from a key 802, the key controller 804 looks up the appropriate key code for that key 802 and transmits same along a key code path 808 (e.g., a keyboard cable) to the computer. Any key codes relating to or affecting the handheld media device are processed by a software application in the computer. The appropriate signals, if any, are then transmitted along a media device signal path 810 (e.g., a media device cable) back to the built-in docking station 806 and thereafter to the handheld media device. Recharging of the handheld media device may be accomplished through the built-in docking station 806 or an optional separate power supply 812, such as a power cable.

A functional block diagram of an exemplary keyboard 900 according to another embodiment of the invention is shown in FIG. 9. The keyboard 900 includes a plurality of keys 902, a key controller 904, and a built-in docking station 906, each of which is essentially identical to the respective counterpart in the keyboard 800 of FIG. 8. However, in the keyboard 900, a tap 914 has been inserted in the key code path 908. The tap 914 intercepts the transmitted key codes and routes a copy thereof to the media device signal path 910 and subsequently to the built-in docking station 906 and any handheld media device docked therein. Such an arrangement allows direct access to the handheld media device from the keyboard 900 (i.e., without going through the computer first). The tap 914 used to copy the transmitted key codes from the key code path 910 may be, for example, a signal splitter or any suitable signal tap known to those having ordinary skill in the art. As before, recharging of the handheld media device may be accomplished through the built-in docking station 906 or an optional separate power supply 912, such as a power cable. The power cable can also be used to provide power for operating the handheld media device directly from the keyboard 900 in the event the computer is not turned on. A battery mounted in the keyboard 900 may also be used to power the keyboard 900 and the handheld media device.

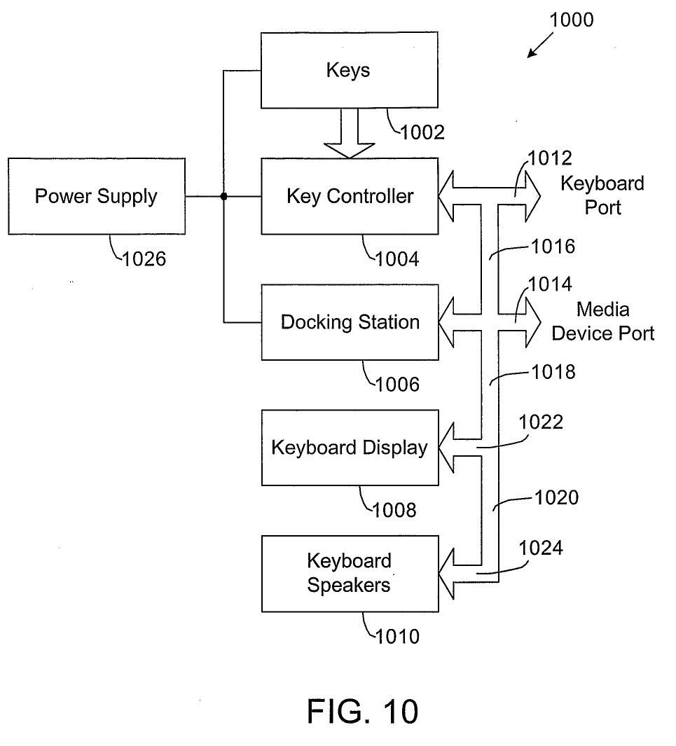

FIG. 10 is a functional block diagram of another exemplary keyboard 1000 according to embodiments of the invention. The keyboard 1000 has a plurality of keys 1002, a key controller 1004, and a built-in docking station 1006, all of which are similar to their counterparts in the keyboards 800 and 900 of FIGS. 8 and 9. In addition, the keyboard 1000 may also have a programmable display 1008 (e.g., an LCD) and speakers 1010 built into the keyboard 1000. Such a keyboard 1000 allows video/picture and audio files stored in the handheld media device as well as various graphics-based features to be viewed and played back while the handheld media device is docked in the built-in docking station 1006. In this respect, the functional block diagram of FIG. 10 may represent the keyboard 700 of FIG. 7, and to a degree, the keyboards 500 and 600 of FIGS. 5 and 6 as well.

In operation, a tap 1016 intercepts the transmitted key codes from the key code controller 1004 and routes a copy thereof to the media device signal path 1014, where they are subsequently sent to the built-in docking station 1006 and any handheld media device docked therein. In response to receiving the key codes, the handheld media device generates the appropriate video and/or audio signals and transmits same through the built-in docking station 1006 and along the media device signal path 1014. Taps 1018 and 1020 may then be used to intercept the video and/or audio signals, respectively, and provide the signals to the display 1008 through a video signal path 1022, and the speakers 1010 through an audio signal path 1024. Recharging of the handheld media device may be accomplished through the built-in docking station 1006, or an optional separate power supply 1026, such as a power cable may also be used. As before, the power cable can also be used to provide power for operating the handheld media device directly from the keyboard 1000 in the event the computer is not turned on. A battery mounted in the keyboard 1000 may also be used to power the keyboard 1000, the handheld media device, the display 1008, and the speakers 1010.

While the present invention has been described with reference to one or more particular embodiments, those skilled in the art will recognize that many changes may be made thereto without departing from the spirit and scope of the present invention. For example, although the built-in docking station, media reader, speakers, and keyboard display of the invention have been shown as being located in a particular spot on the keyboard, those having ordinary skill in the art will understand that the location is exemplary only, and that other suitable locations may certainly be used without departing from the scope of the invention. Each of these embodiments and obvious variations thereof is therefore contemplated as falling within the spirit and scope of the claimed invention, which is set forth in the following claims.

What is claimed is:

1. A method of assembling a computer keyboard, comprising:
providing a keyboard body, the keyboard body having a plurality of keyboard keys thereon;
building a handheld media device docking station into the keyboard body, the handheld media device docking station configured to receive a handheld media device; and
connecting the handheld media device docking station to a media device cable, the media device cable being adapted for carrying data between the handheld media device and a computer.

2. The method according to claim 1, further comprising bundling the media device cable together with a keyboard cable, the media device cable and the keyboard cable forming a keyboard chord.

3. The method according to claim 1, further comprising connecting a power cable to the handheld media device docking station, the power cable configured to carry power to the handheld media device when the handheld media device is docked in the handheld media device docking station.

4. The method according to claim 1, further comprising mounting a battery to the keyboard body, the battery providing power to the handheld media device independently of the computer when the handheld media device is docked in the handheld media device docking station.

5. The method according to claim 1, further comprising mounting a battery to the keyboard body, the battery providing power to the keyboard for operating the keyboard independently of the computer when the handheld media device is docked in the handheld media device docking station.

6. The method according to claim 1, further comprising building speakers into the keyboard body and connecting the speakers to the handheld media device docking station, the speakers operable to play back audio files stored on the handheld media device when the handheld media device is docked in the handheld media device docking station.

7. The method according to claim 1, further comprising building a display into the keyboard body and connecting the display to the handheld media device docking station, the display operable to display video, images, and graphics from the handheld media device when the handheld media device is docked in the handheld media device docking station.

8. The method according to claim 1, wherein the keyboard includes a key controller adapted to generate key codes for the keyboard, further comprising connecting a tap to the key controller, the tap configured to intercept the key codes generated by the key controller.

9. The method according to claim 1, further comprising connecting a tap to the handheld media device docking station, the tap configured to intercept audio data transmitted by the handheld media device through the handheld media device docking station.

10. The method according to claim 1, further comprising connecting a tap to the handheld media device docking station, the tap configured to intercept video data transmitted by the handheld media device through the handheld media device docking station.

11. A computer keyboard, comprising:
a keyboard body having a plurality of keyboard keys thereon;
a handheld media device docking station built in to the keyboard body and configured to receive a handheld media device; and
a media device cable connected to the handheld media device docking station and adapted for carrying data between the handheld media device and a computer.

12. The keyboard according to claim 11, wherein the handheld media device docking station comprises an interface connector adapted to mate with an interface connector of the handheld media device.

13. The keyboard according to claim 12, wherein the interface connector is one of the following types of connectors: Universal Serial Bus (USB), and FireWire.

14. The keyboard according to claim 11, wherein the handheld media device docking station is configured to receive one of the following types of handheld media devices: digital cameras, MP3 players, iPod™.

15. The keyboard according to claim 11, wherein the handheld media device docking station comprises a seat formed as an integral part of the keyboard body for receiving the handheld media device.

16. The keyboard according to claim 11, wherein the handheld media device docking station comprises a cradle mounted in the keyboard body for receiving the handheld media device.

17. The keyboard according to claim 11, wherein the keyboard has one of the following types of keyboard connectors: PS/2, and Universal Serial Bus (USB).

18. The keyboard according to claim 11, further comprising speakers built in to the keyboard body and connected to the handheld media device docking station, the speakers operable to play back audio files stored on the handheld media device when the handheld media device is received in the handheld media device docking station.

19. The keyboard according to claim 11, further comprising a display built in to the keyboard body and connected to the handheld media device docking station, the display operable to display video, images, and graphics from the handheld media device when the handheld media device is received in the handheld media device docking station.

20. A computer keyboard, comprising:
a keyboard body having a plurality of keyboard keys thereon;
a handheld media device docking station built-in to the keyboard body and configured to receive a handheld media device;
a media device cable connected to the handheld media device docking station and adapted for carrying data between the handheld media device and a computer;
a key controller within the keyboard body adapted to generate key codes for the keyboard;
a tap connected to the key controller and the handheld media device docking station, the tap being operable to route a copy of the key codes generated by the key controller to the handheld media device docking station; and
means for providing power to the handheld media device docking station and the keyboard independently of the computer.
